(19) United States
(12) Patent Application Publication
(10) Pub. No.: US 2016/0043312 A1
(43) Pub. Date: Feb. 11, 2016

(54) MEMRISTORS WITH DOPANT-COMPENSATED SWITCHING

(71) Applicant: HEWLETT-PACKARD DEVELOPMENT COMPANY, L.P., Houston, TX (US)

(72) Inventors: Jianhua Yang, Palo Alto, CA (US); Minxian Max Zhang, Palo Alto, CA (US); Gilberto Medeiros Ribeiro, Palo Alto, CA (US); R. Stanley Williams, Palo Alto, CA (US)

(21) Appl. No.: 14/775,811

(22) PCT Filed: Mar. 13, 2013
(86) PCT No.: PCT/US13/30951

§ 371 Date: Sep. 14, 2015

(51) Int. Cl. H01L 45/00

(52) U.S. Cl. CPC H01L 45/145; H01L 45/1233; H01L 45/1608

(57) ABSTRACT

A memristor with dopant-compensated switching, the memristor having a bottom electrode, a top electrode, and an active region sandwiched between the bottom electrode and the top electrode. The active region is made up of an electrically insulating material and an electrically conducting material. The insulating material includes compensating dopants to partially or fully compensate for native dopants in the insulating material. Methods for making the memristor are also disclosed.

### BACKGROUND

Memristors are devices that can be programmed to different resistive states by applying programming energy. After programming, the state of the memristor can be read and remains stable over a specified time period. Large crossbar arrays of memristive elements can be used in a variety of applications, including non-volatile solid state memory, programmable logic, signal processing, control systems, pattern recognition, and other applications.

### BRIEF DESCRIPTION OF THE DRAWINGS

FIG. 1A is an example of a memristor device based on the principles disclosed herein.

FIG. 1B is another example of a memristor device based on principles disclosed herein.

FIGS, 2A-2B, each on coordinates of current (in μA) and voltage (in V), provide a comparison of switching currents for a Ta₂O₅ device without acceptors (FIG. 2A) and with acceptors (FIG. 2B), in accordance with principles disclosed herein.

FIG. 3 is a flow chart depicting an example method for fabricating a memristor in accordance with the examples disclosed herein.

### DETAILED DESCRIPTION

Reference is now made in detail to specific examples of the disclosed oxide-based memristor and specific examples of ways for creating the disclosed oxide-based memristor. When applicable, alternative examples are also briefly described.

As used in the specification and claims herein, the singular forms “a,” “and,” and “the” include plural referents unless the context clearly dictates otherwise.

As used in this specification and the appended claims, “approximately” and “about” mean a ±10% variance caused by, for example, variations in manufacturing processes.

In the following detailed description, reference is made to the drawings accompanying this disclosure, which illustrate specific examples in which this disclosure may be practiced. The components of the examples can be positioned in a number of different orientations and any directional terminology used in relation to the orientation of the components is used for purposes of illustration and is in no way limiting. Directional terminology includes words such as “top,” “bottom,” “front,” “back,” “leading,” “trailing,” etc.

It is to be understood that other examples in which this disclosure may be practiced exist, and structural or logical changes may be made without departing from the scope of the present disclosure. Therefore, the following detailed description is not to be taken in a limiting sense. Instead, the scope of the present disclosure is defined by the appended claims.

Memristors are nano-scale devices that may be used as a component in a wide range of electronic circuits, such as memories, switches, and logic circuits and systems. In a memory structure, a crossbar of memristors may be used. When used as a basis for memories, the memristor may be used to store a bit of information, 1 or 0. When used as a logic circuit, the memristor may be employed as configuration bits and switches in a logic circuit that resembles a Field Programmable Gate Array, or may be the basis for a wired-logic Programmable Logic Array.

When used as a switch, the memristor may either be a closed or open switch in a cross-point memory. During the last few years, researchers have made great progress in finding ways to make the switching function of these memristors behave efficiently. For example, tantalum oxide (TaOₓ)-based memristors have been demonstrated to have superior endurance over other na-no-scale devices capable of electronic switching. In lab settings, tantalum oxide-based memristors are capable of over 10 billion switching cycles whereas other memristors, such as tungsten oxide (WOₓ)- or titanium oxide (TiOₓ)-based memristors, may require a sophisticated feedback mechanism for avoiding over-driving the devices or an additional step of refreshing the devices with stronger voltage pulses in order to obtain an endurance in the range of 10 million switching cycles.

Memristor devices typically may comprise two electrodes sandwiching an insulating layer. One or more conducting channels in the insulating layer between the two electrodes may be formed that are capable of being switched between two states, one in which the conducting channel forms a conductive path between the two electrodes (“ON”) and one in which the conducting channel does not form a conductive path between the two electrodes (“OFF”).

A memristor may comprise a switching material, such as TiO₂ or TaO₂, sandwiched between two electrodes. Memristive behavior is achieved by moving mobile species (e.g., ions or vacancies) in or out of the switching material (specifically, forming a conductive channel between the two electrodes (“ON”) or removing the conductive channel (“OFF”)). Initially, when the memristor is first fabricated, the entire switching material is nonconductive. As such, an electroforming process may be required to form the conductive channel in the switching material between the two electrodes. A known electroforming process, often simply called “forming”, includes applying a sufficiently high (threshold) voltage across the electrodes for a sufficient length of time to cause the conductive channel (or active region) in the switching material to form. The threshold voltage and the length of time required for the electroforming process may depend upon the type of material used for the switching material, the first electrode, and the second electrode.

Electroforming-free devices may be desired, and effort has gone into developing such electroforming-free devices. The conventional electroforming-free devices may consist of a relatively thick conductive suboxide (e.g., Ti₄O₇; from a few nanometers thick to a few hundred nanometers thick in some examples and from 10 to 20 nm thick in other examples) and a relatively thin full oxide, (e.g., TiO₂ or Ta₂O₅; about 10 nm or less in some examples and about 5 nm or less in other examples). However, because these n-type oxides may have too many native donors (e.g. oxygen vacancies) and also because they may need to be thin to be electroforming-free, the device may be too leaky, even in the OFF state (high resistance state). This results in a large switching current and smaller OFF/ON resistance ratio, which may become an issue for the commercialization of memristors.

In accordance with the teachings herein, dopants in these oxides, specifically, acceptor dopants where the native dopants are donors, can reduce the leakage current by compensating the donors, especially from the matrix oxides surrounding the channels. By adding acceptor dopants into the thin full oxide layer, a smaller switching current and a larger OFF/ON resistance ratio may be obtained. Likewise, where the native dopants are acceptors, donor dopants may be used to compensate. A further description of this case of acceptor native dopants is set forth below.

Oxygen vacancies may serve as native donors in n-type oxide and nitrogen vacancies may serve as native donors in n-type nitride semiconductors. Adding acceptors, such as Al, Fe, Co, or Ni, in TiO₂ or Si, Hf, Al, Fe, Co, or Ni, in Ta₂O₅, for example, can compensate these donors and make the thin full oxide semiconductor more resistive by a few orders of magnitude.

Suitable acceptors may be determined by considering the valence state of the transition metal in the oxide or nitride and selecting an element having a lower valence state as the acceptor. For example, Ti has a valence state of +4.Al(+3), Fe(+3), Co(+3), and Ni(+3) all have valence states less than 4. Likewise, Ta has a valence state +5, and Si(+4), Hf(+4), Al, Fe, Co, and Ni all have valence states less than 5.

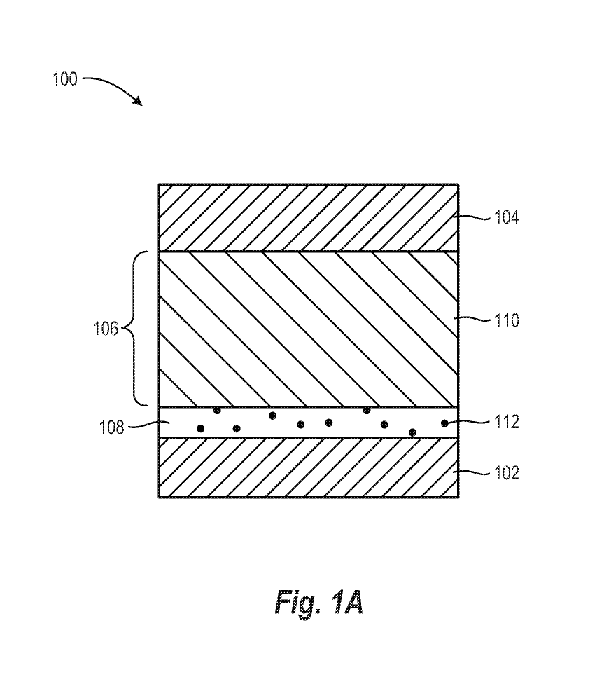

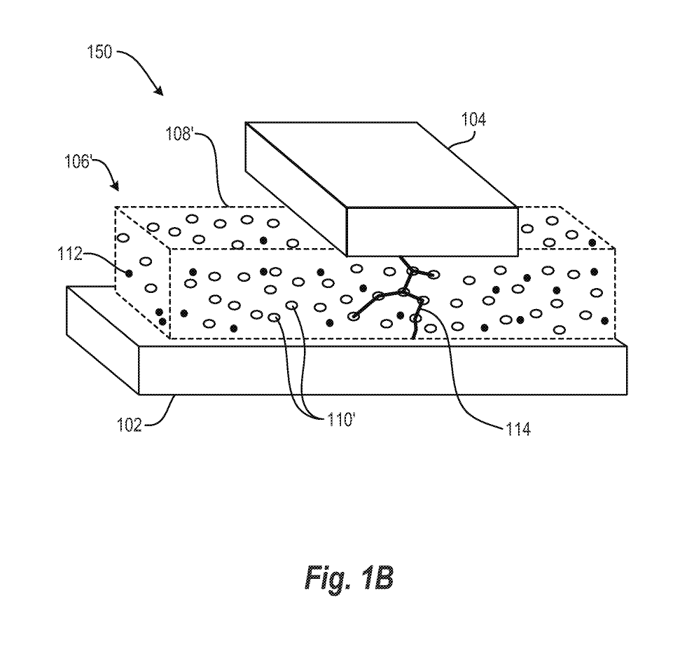

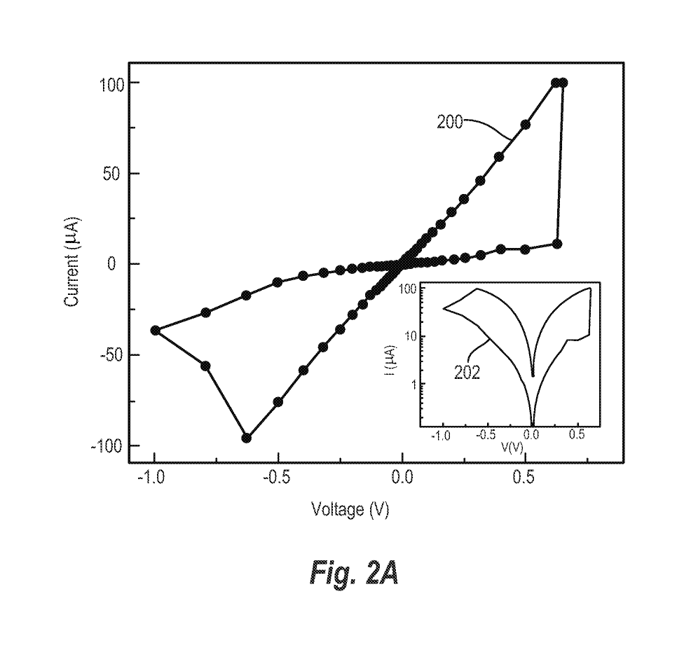

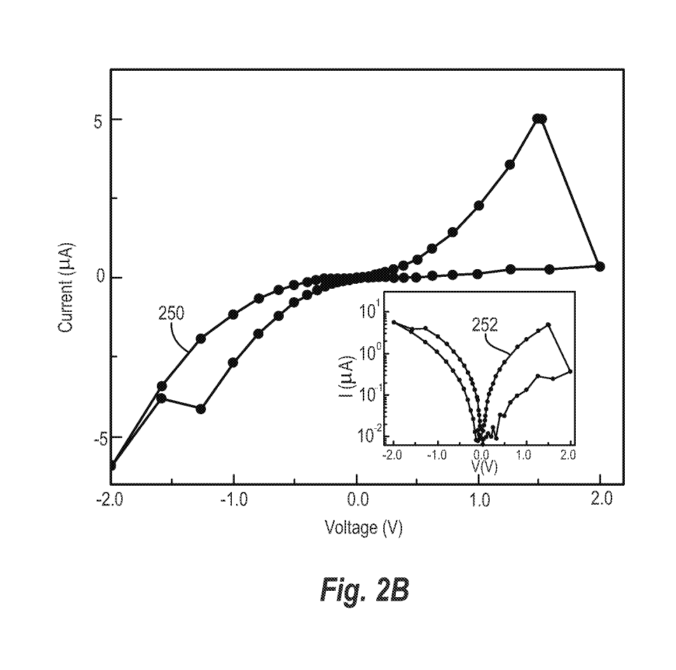

FIG. 1A depicts an example of a device structure in accordance with the teachings herein. The device 100 may have a bottom electrode 102 and a top electrode 104. An active region 106 may be sandwiched between the two electrodes 102, 104. The active region 106 may be made up of two layers, a relatively thinner full oxide layer 108 and a relatively thicker sub-oxide layer 110. The full oxide layer 108 is fabricated in a way to minimize the oxygen deficiency, but in practice it is very difficult for many switching materials, such as TiO₂, to be free of native dopants. The sub-oxide layer 110 may have a significant oxygen deficiency, such as provided by many oxygen vacancies. This structure 100 may be employed in electroforming-free memristors.

The bottom electrode 102 may be any conducting material, non-limiting examples of which include platinum (Pt), titanium nitride (TiN), tantalum nitride (TaN), tungsten (W) , tantalum (Ta), iridium (Ir), ruthenium (Ru), ruthenium oxide (RuO₂), iridium oxide (IrO₂), aluminum (Al), copper (Cu), titanium (Ti), niobium (Nb), molybdenum (Mo), any form of conductive carbon, and heavily-doped semiconductor materials, such as silicon (Si). The top electrode 104 may be selected from the same list as the bottom electrode 102 and may be the same or different. The thickness of each of the bottom electrode 102 and top electrode 104 may be in the range of about 5 to 100 nm.

As indicated above, acceptor dopants 112 may be added to the full oxide layer 108. Acceptor dopants 112 may reduce high leakage current, high operation energy, increase the OFF/ON resistance memory window and provide very low cost, but high-performance (low switching energy and large ON/OFF ratio) and low-energy devices. In an example, the concentration of the dopant may be in the range of about 0.1 to 40 at %; in another example, the concentration may range from about 5 to 30 at %. It appears that there are no deleterious effects in the event of over-compensation. While the dopants 112 may be acceptor dopants in FIG. 1A, they may alternatively be donor dopants under conditions described below where the native dopants are acceptor species.

FIG. 1B depicts another example of a device structure in accordance with the teachings herein. The device 150 shares many of the same features as the device 100 of FIG. 1A, including bottom electrode 102 and top electrode 104. In this case, an active region 106′ may be sandwiched between the two electrodes 102, 104 and may be made up of two phases, a resistive, or non-conducting, or insulating, first phase 108′ that serves as an insulating matrix and a conducting, or metallic-like, second phase 110′ embedded or dispersed in the resistive first phase. The material comprising the non-conducting first phase 108′ may include, for instance, a transition metal oxide, such as tantalum oxide (Ta₂O₅), titanium oxide (TiO₂), yttrium oxide (Y₂O₃), hafnium oxide (HfO₂), zirconium oxide (ZrO₂), etc. or a metal oxide, such as aluminum oxide (Al₂O₃), calcium oxide (CaO), magnesium oxide (MgO), etc.

As in FIG. 1A, the dopants (acceptor or donor) 112 may be dispersed in the non-conducting phase 108′.

In one example, the active region 106′ may be relatively larger than the first electrode 102 and the second electrode 104. In another example, the active region 106 may be relatively smaller than the first electrode 102 and the second electrode 104.

In an example, the conducting second phase 110′ may comprise a sub-oxide (or sub-nitride) of the non-conducting oxide (or nitride) first phase 108′. In another example, the conducting second phase 110′ may comprise a compound that is formed between the material comprising the first phase and an added material. As an example, consider the system TaO₂:SiO₂. This system may be resolved into Ta₂Si:Ta₂O₅:SiO₂. In this case, the first, insulating phase, or matrix phase, 108′ may be a mixture of Ta₂O₅ and SiO₂, while the second, conducting phase, or dispersed phase, 110 may be Ta₂Si, which is dispersed in the first phase and may form a conducting channel 114. It should be noted that the first phase 108′ may actually be a mixture of two (or more) insulating phases or a solid solution. For convenience, since such materials are insulating, the term “phase” when applied to the phase 108′ includes both single and multiple insulating (or resistive or non-conducting or matrix) phases.

An annealing operation or other thermal forming operation, such as heating by exposure to a high temperature environment or by exposure to electrical resistance heating, may be employed to form the compound conducting channels 114. For many systems, such as Ta—O, Hf—O, Y—O, and the like, electrical resistance heating that generates an elevated temperature is sufficient to form the compound conducting channels 114 locally inside the cross-sectional area. The temperature in the localized region inside the device can be several hundred degrees higher than the rest of the materials and can therefore enhance the chemical reactions in the switching materials to form the compound conducting channels 114.

In the device 150 depicted in FIG. 1B, the bottom electrode 102 and the top electrode may be any of the same materials as described above with regard to the device 100 depicted in FIG. 1A. As with the device 100, the top electrode 104 may be selected from the same list as the bottom electrode 102 and may be the same or different. The thickness of each of the bottom electrode and top electrode may be in the range of about 5 to 100 nm.

As depicted in FIG. 1B, the memristor 150 includes the first electrode 102 positioned below the second electrode 104, in which the first electrode 102 may be in a crossed arrangement with respect to the second electrode 104, such that the first electrode 102 is arranged substantially perpendicularly to the second electrode 104. However, it will be appreciated that in other examples, the first electrode 102 and the second electrode 104 may be arranged at any angle with respect to each other, including parallel, depending upon the application. This is also true of the memristor 100 shown in FIG. 1A.

An example of the improvement provided by adding acceptor dopants is provided in the comparison FIGS. 2A and 2B. The devices were 100 μm devices (100 μm devices refer to the diameter of device area.) Both devices had a bottom electrode 102 of Pt and a top electrode 104 of Ta. The thickness of the bottom electrode 102 was 100 nm and the thickness of the top electrode 104 was 20 nm. Both devices had the structure depicted in FIG. 1B and included an active region 106 of a full oxide layer 108′, Ta₂O₅, and a channel 114 of a sub-oxide 110′ of TaO₂. As prepared, the active region 106′ was Ta₂O₅. Upon electroforming, TaO₂ channels 114 were obtained, with 10 to 60 at % oxygen in the channels. This is to be compared with oxygen in the full oxide of about 71.4 at %.

In FIG. 2A, the main curve 200 depicts the I-V curve, where current is on a linear scale, whereas the insert curve 202 depicts the same data, but with current on a logarithmic scale. Likewise, in FIG. 2B, the main curve 250 depicts the I-V curve, where current is on a linear scale, whereas the insert curve 252 depicts the same data, but with current on a logarithmic scale.

FIG. 2A depicts a TaOₓ device without dopant compensation, whereas FIG. 2B depicts a TaOₓ device with dopant compensation, specifically, Si. The dopant concentration was 30 at % and was formed using codeposition from two targets (Ta₂O₅ and SiO₂).

Adding Si dopants into a full oxide layer, such as Ta₂O₅ in the TaOₓ device shown in FIG. 2B, may provide the following benefits:

1. Switching current decreases by 20 times (5 μA in FIG. 2B as compared with 100 μA in FIG. 2A);

2. OFF/ON resistance ratio increases by 10 times; and

3. Switching energy decreases by over 100 times.

If the insulating layer (e.g., Ni₁₋ₓO) in the bi-layer stack is “p-type” instead, such as Ti₄O₇/Ni₁₋ₓO, then donors, such as Ti or Al may be used to compensate the native acceptor dopants and significantly reduce the current level through the Ni₁₋ₓO layer, resulting in low energy operation. Here, Ni is in the 2+ valence state, so dopants such as Ti(+4) and Al(+3) may be used for the compensation.

Thus, depending on the nature of the native dopants already present, a dopant of the opposite nature may be added to compensate. Extra oxygen ions in p-type oxides (such as Ni oxide, Fe oxide and Co oxide) may serve as acceptor dopants. Adding donor dopants in these semiconductors, such as Al or Si, can compensate the acceptors and make the full oxide 108, 108′ more resistive, too.

Examples for processes for adding the compensating dopant (acceptor or donor) may include, without limitation, codeposition with the full oxide 108 or 158, using two targets or using a target that has desired concentration; atomic layer deposition (ALD) involving layering the elements; reactive sputtering; thermal oxidation; or ion implantation. Any of these processes may be used to form the device 100, 150 of FIGS. 1A and 1B.

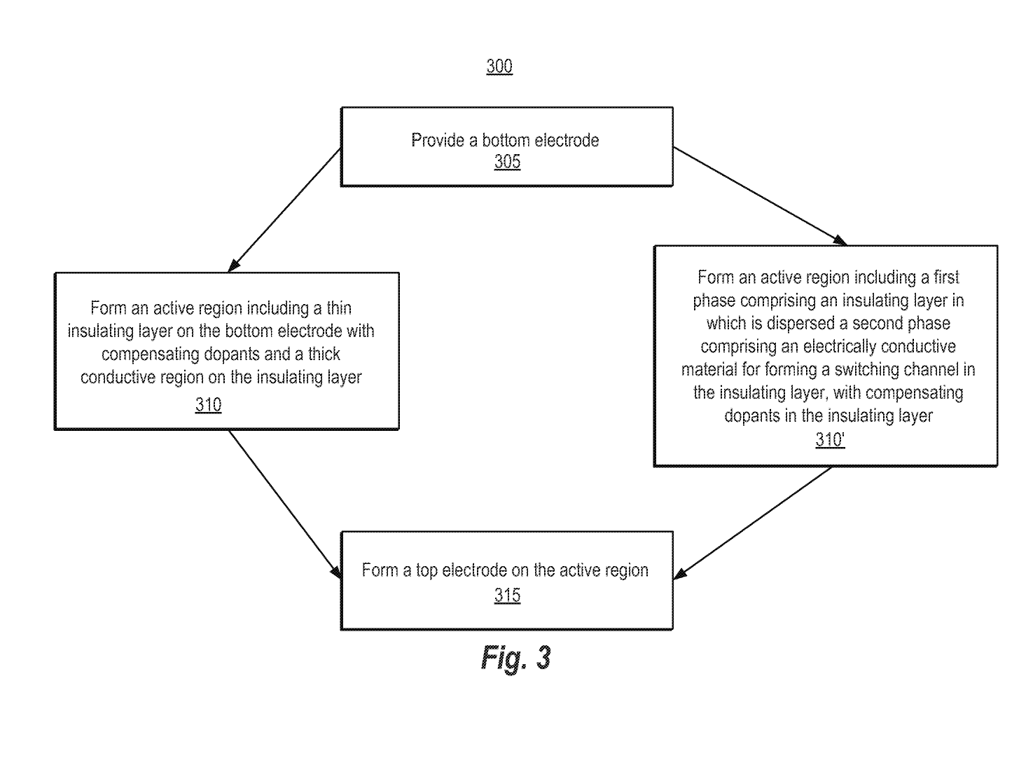

Turning now to FIG. 3, a method 300 for forming a memristor with dopant-compensated switching is shown. The method 300 may include providing 305 a bottom electrode 102. The bottom electrode 102 may serve as a substrate or may be formed on a substrate (not shown). If the bottom electrode 102 is formed on a substrate (not shown), then the substrate may be an insulating material, such as silica (SiO₂), alumina (Al₂O₃), silicon nitride (Si₃N₄), or other insulating material. The bottom electrode 102 may be formed by any number of methods, including, but not limited to, evaporation of metal, sputtering, or ALD.

Next, one of at least two paths may be followed, both involving forming an active region 106, 106′ on the bottom electrode 102. In the first path, the active region 106 may be formed 310 by providing a relatively thin insulating layer, such as a full oxide or full nitride layer, 108 on the bottom electrode 102. The full oxide or full nitride layer 108 may be formed by any number of methods, including, but not limited to, sputtering, ALD, evaporation, or chemical vapor deposition (CVD). The full oxide or full nitride layer 108 may be formed to a thickness within a range of a few nanometers to a few hundred nanometers. The insulating layer 108 may be doped with one or more compensating dopants 112, either during deposition of the full oxide or full nitride or after, such as by ion implantation,

A relatively thick conductive layer, such as a sub-oxide or sub-nitride layer, 110 may be formed on the insulating layer 108, with sub-oxide formed on full oxide and sub-nitride formed on full nitride. The sub-oxide or sub-nitride layer 110 may be formed by any number of methods, including those listed for the full oxide/full nitride layer. The sub-oxide or sub-nitride layer 110 may be formed to a thickness up to about 10 nm. It can be thus appreciated that the full oxide or full nitride layer 108 is relatively thin compared to the sub-oxide or sub-nitride layer 110 and that the sub-oxide or sub-nitride layer is relatively thick compared to the full oxide or full nitride layer 108.

In the second path, the active region 106′ may be formed 310′ by providing a first phase 108′ comprising an insulating layer in which is dispersed a second phase 110′ comprising an electrically conductive material for forming a switching channel 114 in the insulating layer. The insulating layer 108′ may be doped with one or more compensating dopants 112, either during deposition of the insulating layer or after, such as by ion implantation.

A top electrode 104 may be formed 315 on the active region 106, 106. The top electrode 104 may be formed by any number of methods, including those listed above for forming the bottom electrode 102.

The foregoing discussion has been directed to systems in which the insulating material and the conducting material may be metal oxides, or, in the alternative, metal nitrides. However, other materials may be used for the insulating and conducting materials. Examples include, without limitation, metal carbides, metal sulfides, metal phosphides, and mixed systems, such as ternary (e.g., TaNₓO_{y}) and above (e.g., quaternary), as well as ternary oxides, quaternary oxides, or other complex oxides, such as strontium titanate oxide (STO) or praseodymium calcium manganese oxide (POMO).

The resulting devices prepared in accordance with the teachings herein evidence high-performance (low switching energy and large ON/OFF ratio) and low-energy.

What is claimed is:

1. A memristor with dopant-compensated switching, the memristors including:
a bottom electrode;
a top electrode; and
an active region sandwiched between the bottom electrode and the top electrode, the active region comprising an electrically insulating material and an electrically conducting material,
wherein the insulating material includes compensating dopants to partially or fully compensate for native dopants in the insulating material.

2. The memristor of claim 1 wherein the conductive material comprises a sub-oxide and the insulating material comprises a full oxide or wherein the conductive material comprises a sub-nitride and the insulating material comprises a full nitride.

3. The memristor of claim 2 wherein the compensating dopants are acceptor dopants.

4. The memristor of claim 3 wherein the compensating dopants are selected from metals that have one or more valences below that of the metal comprising the metal oxide or the metal nitride.

5. The memristor of claim 2 wherein the compensating dopants are donor dopants.

6. The memristor of claim 5 wherein the compensating dopants are selected from metals that have one or more valences above that of the metal comprising the metal oxide or the metal nitride.

7. The memristor of claim 1 wherein the active region comprises a relatively thick conductive material and a relatively thin insulating material sandwiched between the bottom electrode and the top electrode.

8. The memristor of claim 1 wherein the active region comprises a matrix of the insulting layer in which is dispersed the electrically conductive material for forming a switching channel in the insulating layer.

9. A method for providing a memristor with dopant-compensated switching, the memristor including:
a bottom electrode;
a top electrode; and
an active region positioned between the bottom electrode and the top electrode, wherein the active region includes either a relatively thin insulating layer on the bottom electrode and a relatively thick conductive layer on the insulating layer or a first phase comprising an insulating layer in which is dispersed a second phase comprising conductive material for forming a switching channel in the insulating layer, with compensating dopants in the insulating layer to partially or fully compensate for native dopants in the insulating material, the process comprising:
providing the bottom electrode;
forming the active region on the bottom electrode; and
forming the top electrode on the active region.

10. The method of claim 9 wherein the insulating layer comprises a full oxide and the conductive layer comprises a sub-oxide or wherein the insulating material comprises a full nitride and the conductive material comprises a sub-nitride.

11. The method of claim 10 wherein the compensating dopants are acceptor dopants.

12. The method of claim 11 wherein the compensating dopants are selected from metals that have one or more valences below that of the metal comprising the metal oxide or the metal nitride.

13. The method of claim 10 wherein the compensating dopants are donor dopants.

14. The method of claim 13 wherein the compensating dopants are selected from metals that have one or more valences above that of the metal comprising the metal oxide or the metal nitride.

15. The method of claim 9 wherein the dopants and the thin insulating layer are formed at the same time.
